(19) United States
(12) Patent Application Publication
(10) Pub. No.: US 2026/0003571 A1
(43) Pub. Date: Jan. 1, 2026

(54) Floating-Point Data Precision Conversion Method and Apparatus

(71) Applicant: Huawei Technologies Co., Ltd., Shenzhen (CN)

(72) Inventors: Wei Hsiang Wu, Hong Kong (CN); Yuanyong Luo, Shenzhen (CN); Minqi Chen, Hangzhou (CN); Zhongxing Zhang, Beijing (CN)

(73) Assignee: Huawei Technologies Co., Ltd., Shenzhen (CN)

(21) Appl. No.: 19/316,588

(22) Filed: Sep. 2, 2025

Related U.S. Application Data
(63) Continuation of application No. PCT/CN2024/078993, filed on Feb. 28, 2024.

(30) Foreign Application Priority Data
Mar. 3, 2023 (CN) 202310238789.3

(51) Int. Cl. G06F 7/483; G06F 7/499; H03M 7/24

(52) U.S. Cl. CPC G06F 7/483; G06F 7/49947; H03M 7/24

(57) ABSTRACT

A floating-point data precision conversion method includes determining a bit width of a second mantissa field based on a coded value of a first exponent field. The floating-point data precision method further includes determining a reserved coded value and a discarded coded value in a first mantissa field. The floating-point data precision method further includes, if the coded value of the first exponent field is greater than or equal to a first preset threshold, performing a rounding operation on the reserved coded value based on a coded value that starts from a most significant bit and whose bit width is a preset bit width in the discarded coded value, to obtain a coded value of the second mantissa field.

### CROSS-REFERENCE TO RELATED APPLICATIONS

This is a continuation of International Patent Application No. PCT/CN2024/078993, filed on Feb. 28, 2024, which claims priority to Chinese Patent Application No. 202310238789.3, filed on Mar. 3, 2023, which are both incorporated by reference.

### TECHNICAL FIELD

Embodiments of this disclosure relate to the field of chip technologies, and in particular, to a floating-point (FP) data precision conversion method and apparatus.

### BACKGROUND

With development of the artificial intelligence (AI) field, a neural network (NN) keeps increasing in scale, and requirements for computing power for training the NN are also increasing. Currently, a sharp growth in model training computing power causes high overheads in chip costs. Using existing FP 16 mixed precision data and brain FP (BF) 16 precision data have excessively high costs. However, using low-bit data for computation can implement lossless training for a large model of a transformer. Therefore, low-bit FP training is a future trend for large model training.

However, in an NN training process, a mixed-precision computing scenario involves mutual conversion between FP data of different precision. Format conversion from low-precision FP data to high-precision FP data is error-free conversion, while format conversion from high-precision FP data into low-precision FP data involves a rounding operation performed on the high-precision FP data. As a result, a conversion error is caused thereof, affecting training precision of model training.

### SUMMARY

Embodiments of this disclosure provide an FP data precision conversion method and apparatus, reducing a conversion error of converting high-precision FP data into low-precision FP data.

To achieve the foregoing objective, the following technical solutions are applied in embodiments of this disclosure.

According to a first aspect, an embodiment of this disclosure provides an FP data precision conversion method. First FP data includes a first exponent field and a first mantissa field. Second FP data includes a second mantissa field. Precision of the first FP data is higher than precision of the second FP data. The method includes: determining a bit width of the second mantissa field based on a coded value of the first exponent field; determining a reserved coded value and a discarded coded value in the first mantissa field, where the reserved coded value includes a coded value that starts from a most significant bit (MSB) in the first mantissa field and whose bit width is the same as the bit width of the second mantissa field; and if the coded value of the first exponent field is greater than or equal to a first preset threshold, performing a rounding operation on the reserved coded value based on a coded value that starts from an MSB and whose bit width is a preset bit width in the discarded coded value, to obtain a coded value of the second mantissa field; or if the coded value of the first exponent field is less than the first preset threshold, performing a rounding operation on the reserved coded value based on the MSB of the discarded coded value, to obtain the coded value of the second mantissa field.

Therefore, according to the FP data precision conversion method provided in this embodiment of this disclosure, high-precision FP data is converted into low-precision FP data. The performing the rounding operation on the reserved coded value based on the coded value that starts from the MSB and whose bit width is the preset bit width in the discarded coded value may be understood as a stochastic rounding (SR) manner, and the performing a rounding operation on the reserved coded value based on the MSB of the discarded coded value may be understood as a manner of rounding half away from zero (TA rounding manner). In data format conversion, selection between the SR manner and the TA rounding manner can be understood as a hybrid rounding (HR) manner. When the coded value of the first exponent field is greater than or equal to the first preset threshold, the SR manner is used. When the coded value of the first exponent field is less than the first preset threshold, the TA rounding manner is used. Therefore, different rounding manners are provided, so that a conversion error during data format conversion can be reduced, data conversion efficiency can be improved, and training precision of model training can be improved.

In a possible design, the rounding operation includes a carrying operation and a discarding operation, and the performing the rounding operation on the reserved coded value based on the coded value that starts from the MSB and whose bit width is the preset bit width in the discarded coded value, to obtain the coded value of the second mantissa field includes: when the coded value that starts from the MSB and whose bit width is the preset bit width in the discarded coded value is greater than or equal to a second preset threshold, performing a carrying operation on a least significant bit (LSB) of the reserved coded value, and performing a discarding operation on the discarded coded value, where a coded value obtained through carrying of the reserved coded value is the coded value of the second mantissa field; or when the coded value that starts from the MSB and whose bit width is the preset bit width in the discarded coded value is less than the second preset threshold, performing a discarding operation on the discarded coded value, where the reserved coded value is the coded value of the second mantissa field. The second preset threshold is a coded value that starts from an LSB and whose bit width is the preset bit width in the discarded coded value.

In this design, in the SR manner, the second preset threshold for comparison is a coded value that starts from the LSB and whose bit width is the preset bit width in the discarded coded value. The second preset threshold is generated without an additional random number generator, and there is no performance bottleneck of random number generation, so that efficiency of converting high-precision FP data into low-precision FP data is improved, and hardware overheads are lower.

In a possible design, the rounding operation includes a carrying operation and a discarding operation, and the performing the rounding operation on the reserved coded value based on the MSB of the discarded coded value, to obtain the coded value of the second mantissa field includes: when the MSB of the discarded coded value is greater than or equal to a third preset threshold, performing a carrying operation on an LSB of the reserved coded value, and performing a discarding operation on the discarded coded value, where a coded value obtained through carrying of the reserved coded value is the coded value of the second mantissa field; or when the MSB of the discarded coded value is less than the third preset threshold, performing a discarding operation on the discarded coded value, where the reserved coded value is the coded value of the second mantissa field.

In this design, the third preset threshold may be 0 or 1, and the MSB of the discarded coded value is compared with the third preset threshold. This belongs to the TA rounding manner. In addition to the TA rounding manner, a rounding manner away from an even number, a rounding manner away from an odd number, and the like may be further included. However, in comparison with other rounding manners, in the TA rounding manner, a hardware implementation area is smaller, power consumption overheads are less, and a data resolution is higher.

In a possible design, the first preset threshold is determined by traversing a plurality of pieces of first FP data.

In this design, the first preset threshold is an adjustable parameter, and accuracy of data format conversion can be improved by setting a proper value of the first preset threshold.

In a possible design, the first FP data further includes a sign field, and the second FP data further includes the sign field, a prefix code field, and a second exponent field. The prefix code field indicates a bit width of the second exponent field, and before the determining the bit width of the second mantissa field based on the coded value of the first exponent field, the method further includes: determining a bit width of the prefix code field, a coded value of the prefix code field, a bit width of the second exponent field, and a coded value of the second exponent field based on the coded value of the first exponent field.

In this design, during data format conversion, the sign field of the second FP data may be obtained based on the sign field of the first FP data, the prefix code field and the second exponent field of the second FP data may be obtained based on the first exponent field of the first FP data, and the second mantissa field of the second FP data may be obtained based on the first mantissa field of the first FP data. In the second FP data, the bit width of the second exponent field is indicated by a short prefix code field, so that precision or a bit width of a mantissa field of the second FP data can be effectively improved. In addition, the second FP data that provides precision of only one-bit mantissa can represent a large value range, effectively balancing a relationship among a bit width, a range, and precision of the second FP data. In addition, for the prefix code field, a prefix code coding scheme may be used, which occupies a small bit width, and is convenient to parse the second exponent field and the second mantissa field.

According to a second aspect, an embodiment of this disclosure provides an FP data precision conversion apparatus. First FP data includes a first exponent field and a first mantissa field. Second FP data includes a second mantissa field. Precision of the first FP data is higher than precision of the second FP data. The apparatus includes: a bit width computation unit, configured to determine a bit width of the second mantissa field based on a coded value of the first exponent field; a mantissa field computation unit, configured to determine a reserved coded value and a discarded coded value in the first mantissa field, where the reserved coded value includes a coded value that starts from an MSB in the first mantissa field and whose bit width is the same as the bit width of the second mantissa field; and a rounding operation unit, configured to: if the coded value of the first exponent field is greater than or equal to a first preset threshold, perform a rounding operation on the reserved coded value based on a coded value that starts from an MSB and whose bit width is a preset bit width in the discarded coded value, to obtain a coded value of the second mantissa field, where the rounding operation unit is further configured to: if the coded value of the first exponent field is less than the first preset threshold, perform a rounding operation on the reserved coded value based on the MSB of the discarded coded value, to obtain the coded value of the second mantissa field.

For beneficial effects of the second aspect, refer to the descriptions of the first aspect.

In a possible design, the rounding operation includes a carrying operation and a discarding operation. The rounding operation unit is further configured to: when the coded value that starts from the MSB and whose bit width is the preset bit width in the discarded coded value is greater than or equal to a second preset threshold, perform a carrying operation on an LSB of the reserved coded value, and perform a discarding operation on the discarded coded value, where a coded value obtained through carrying of the reserved coded value is the coded value of the second mantissa field; or when the coded value that starts from the MSB and whose bit width is the preset bit width in the discarded coded value is less than the second preset threshold, perform a discarding operation on the discarded coded value, where the reserved coded value is the coded value of the second mantissa field. The second preset threshold is a coded value that starts from an LSB and whose bit width is the preset bit width in the discarded coded value.

In a possible design, the rounding operation includes a carrying operation and a discarding operation, and the rounding operation unit is further configured to: when the MSB of the discarded coded value is greater than or equal to a third preset threshold, perform a carrying operation on an LSB of the reserved coded value, and perform a discarding operation on the discarded coded value, where a coded value obtained through carrying of the reserved coded value is the coded value of the second mantissa field; or when the MSB of the discarded coded value is less than the third preset threshold, perform a discarding operation on the discarded coded value, where the reserved coded value is the coded value of the second mantissa field.

In a possible design, the first preset threshold is determined by traversing a plurality of pieces of first FP data.

In a possible design, the first FP data further includes a sign field, and the second FP data further includes the sign field, a prefix code field, and a second exponent field. The prefix code field indicates a bit width of the second exponent field, and the bit width computation unit is further configured to determine a bit width of the prefix code field, a coded value of the prefix code field, a bit width of the second exponent field, and a coded value of the second exponent field based on a coded value of the first exponent field.

According to a third aspect, an embodiment of this disclosure provides an FP data precision conversion apparatus, including a processor and a memory. The memory stores computer instructions, and after executing the computer instructions, the processor performs the FP data precision conversion method in any one of the foregoing aspects and the possible implementations.

According to a fourth aspect, an embodiment of this disclosure provides a computer-readable storage medium, including computer instructions. When the computer instructions are run on an electronic device, the electronic device is enabled to perform the FP data precision conversion method according to any one of the foregoing aspects and the possible implementations.

According to a fifth aspect, an embodiment of this disclosure provides a computer program product. When the computer program product is run on a computer or a processor, the computer or the processor is enabled to perform the FP data precision conversion method according to any one of the foregoing aspects and the possible implementations.

According to a sixth aspect, an embodiment of this disclosure provides a system. The system may include a wireless access device and at least one electronic device in any possible implementation of any one of the foregoing aspects. The electronic device and the wireless access device may perform the FP data precision conversion method in any one of the foregoing aspects and the possible implementations.

It may be understood that any FP data precision conversion apparatus, computer-readable storage medium, computer program product, or the like provided above may be used for the corresponding method provided above. Therefore, for beneficial effects that can be achieved by the FP data precision conversion apparatus, the computer-readable storage medium, or the computer program product, refer to the beneficial effects in the corresponding method. Details are not described herein again.

These aspects or other aspects in this disclosure are more concise and comprehensible in the following descriptions.

### BRIEF DESCRIPTION OF DRAWINGS

FIG. 1 is a diagram of a data structure according to an embodiment of this disclosure.

FIG. 2 is a diagram of distribution of exponent field-mantissa field bit width according to an embodiment of this disclosure.

FIG. 3 is a diagram of a system or a device in which an FP data precision conversion apparatus is used according to an embodiment of this disclosure.

FIG. 4 is a diagram of a structure of a system-on-chip (SoC) according to an embodiment of this disclosure.

FIG. 5 is a flowchart of an FP data precision conversion method according to an embodiment of this disclosure.

FIG. 6 is a diagram of a mantissa field of single-precision FP (FP32) data converted into HiFloat8 data in an SR rounding manner according to an embodiment of this disclosure.

FIG. 7 is a diagram of a mantissa field of half-precision FP (FP16) data converted into HiFloat8 data in an SR rounding manner according to an embodiment of this disclosure.

FIG. 8 is a diagram of distribution of an HR manner according to an embodiment of this disclosure.

FIG. 9 is a flowchart of NN training according to an embodiment of this disclosure.

FIG. 10 is another flowchart of NN training according to an embodiment of this disclosure.

FIG. 11 is another flowchart of NN training according to an embodiment of this disclosure.

FIG. 12 is a diagram of composition of an FP data precision conversion apparatus according to an embodiment of this disclosure.

### DETAILED DESCRIPTION

For ease of understanding, some concepts related to embodiments of this disclosure are described for reference by using examples. Details are as follows.

An NN training process mainly includes forward computation, backward computation, and weight update. A computation mode in the training process includes general matrix multiplication (GEMM) and non-GEMM. A layer corresponding to GEMM computation may be referred to as a matrix multiplication computation layer, and a layer corresponding to non-GEMM computation may be referred to as a non-matrix multiplication computation layer. In some instances, the GEMM includes convolution, transposed convolution, matrix multiplication, and batch matrix multiplication. The non-GEMM includes an activation function, a normalization function, optimizer gradient update computation, and the like. The activation function includes sigmoid, tanh, and rectified linear unit. The normalization function includes batch normalization, layer normalization, instance normalization, and the like.

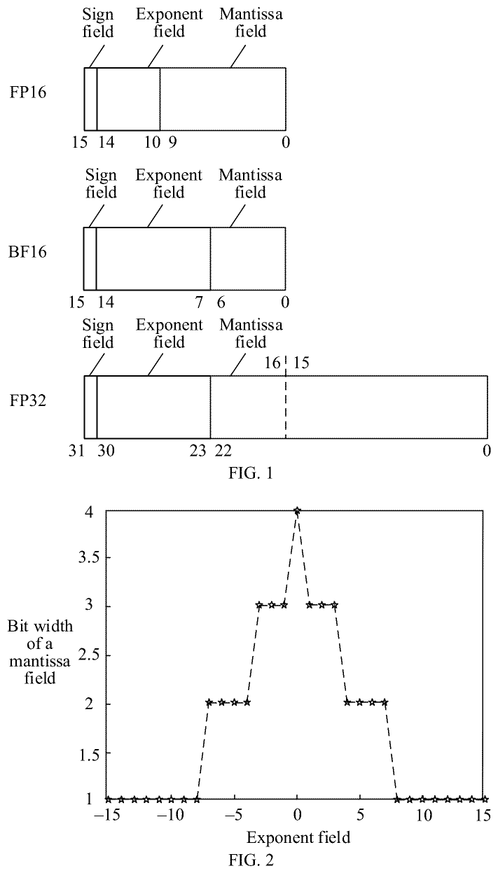

The GEMM may be performed by using FP16, 16-bit brain FP (BF16), or data of lower precision, and the non-GEMM needs to be performed by using data of higher precision such as FP32. The FP32 may also be referred to as a full-precision FP. FIG. 1 is a diagram of a data structure. In some instances, the FP16 includes 16 bits, where one bit at an MSB is a sign field, intermediate five bits are an exponent field, and the remaining 10 bits are a mantissa field. The mantissa field represents a decimal. The BF16 includes 16 bits, where one bit at an MSB is a sign field, intermediate 8 bits are an exponent field, and the remaining 7 bits are a mantissa field. The FP32 includes 32 bits, where one bit at an MSB is a sign field, intermediate 8 bits are an exponent field, and the remaining 23 bits are a mantissa field.

The following describes the technical solutions in embodiments of this disclosure with reference to the accompanying drawings in embodiments of this disclosure. In descriptions in embodiments of this disclosure, “/” means “or” unless otherwise specified. For example, A/B may represent A or B. In this specification, “and/or” describes only an association relationship for describing associated objects and represents that three relationships may exist. For example, A and/or B may represent the following three cases: Only A exists, both A and B exist, and only B exists. In addition, in the descriptions in embodiments of this disclosure, “a plurality of” means two or more.

The terms “first” and “second” mentioned below are merely intended for a purpose of description, and shall not be understood as an indication or implication of relative importance or implicit indication of a quantity of indicated technical features. Therefore, a feature limited by “first” or “second” may explicitly or implicitly include one or more features. In the descriptions of embodiments, unless otherwise specified, “a plurality of” means two or more.

NN training has an increasing requirement for computing power. In some instances, an NN training process may require 100 petaflops (where one petaflop equals 10 trillion mathematical operations per second) initially. In a current transformer model, an NN training process may require 1 billion petaflops. The requirement for computing power has increased by 10 million times. Therefore, to reduce power consumption during NN training, two low-precision FP data formats are defined: 8-bit FP (FP8) (E5M2) and FP8 (E4M3). An FP8 (E5M2) exponent field has five bits, and an FP8 (E5M2) mantissa field has 2 bits. An FP8 (E4M3) exponent field has 4 bits, and an FP8 (E4M3) mantissa field has 3 bits. In a training process of an NN involving forward computation, backward computation, and weight update, mixed precision is used for training, where two FP8 data formats are used for computation in GEMM, and FP32 or FP16 is used for computation in non-GEMM. It may be understood that, in comparison between the GEMM computation performed by using data in the foregoing two low-precision FP data formats and the GEMM computation by using FP16/BF16 data, because a total bit width of the two low-precision FP data formats is half of a total bit width of the FP16/BF16, a data amount of the GEMM computation is reduced to half, thereby reducing power consumption of an NN chip.

However, because a data precision loss is caused during data format conversion in which high-precision FP data is converted into the foregoing two low-precision FP data formats for the GEMM computation, and then the data is converted into a high-precision data format for the non-GEMM computation, for example, the data is converted into an FP16/BF16 data format, training precision of an NN is reduced. To reduce the data precision loss, a scaling operation is introduced into a training process. However, after the scaling operation, distribution statistics need to be collected on data generated by a tensor core, increasing the power consumption of the NN chip. In addition, the two types of low-precision FP data have different performance in precision and dynamic range. User need to select one data format from the two types of low-precision FP data for NN training. The method may not be able to indicate the users for selection, resulting in poor user experience and generalization.

In another NN training method, a block FP is defined for representation of low- precision data, and mixed precision is used during NN training, thereby reducing power consumption of an NN chip. In some instances, during GEMM computation, computation is performed after the data is converted into data in a block FP data format, and during non-GEMM computation, computation is performed after data is converted into data in an FP32 or FP16 data format. During conversion of the data into a block FP data format, the high-precision data is first divided into a plurality of blocks, data distribution in each block is then counted, and data in the block is finally split into a common exponent field, and a sign field and a mantissa field of each piece of data based on the data distribution. In this case, because data in each block has a common exponent, a total bit width of each piece of data in the block is reduced, so that using the data in the block FP data format for training can reduce power consumption of the NN chip.

However, when the data in the block FP data format is used for training, because the block FP data format limits a representation range of the data, a precision loss of the data is caused, thereby reducing training precision of the NN. In addition, different computation layers of the NN have different block division manners, leading to a more complex algorithm procedure. Moreover, a quantization operation needs to be introduced before the GEMM computation, and a dequantization operation needs to be introduced after the GEMM computation, and statistics need to be collected on data analysis. This affects performance of NN training.

Therefore, embodiments of this disclosure provide an FP data precision conversion method. The method relates to data format conversion between first FP data and second FP data. Precision of the first FP data is higher than precision of the second FP data. In the method, an HR manner is used. To be specific, when a coded value of a first exponent field is greater than or equal to a first preset threshold, an SR manner is used; or when the coded value of the first exponent field is less than the first preset threshold, a TA rounding manner is used. Different rounding manners are provided, so that a conversion error during data format conversion can be reduced, data conversion efficiency can be improved, and training precision of model training can be improved.

The method may be applied to the AI field. The FP data precision conversion method may be applied to chips such as a central processing unit (CPU), a graphics processing unit (GPU), a tensor processing unit (TPU), and an NN processing unit (NPU).

Specifically, the second FP data provided in embodiments of this disclosure may be HiFloat8 data. As shown in Table 1, Table 1 shows a coding scheme of the HiFloat8 data.

TABLE 1
Coding scheme of HiFloat8 data

| | | Prefix code field (D): | Exponent | Mantissa |
|---|---|---|---|---|
| HiFloat8 data | Sign field (S) | {value} | field (E) | field (M) |
| Bit width | 1 | 2: {2, 3, 4} | D | 8-3-D |
| (width) | 1 | 3: {0, 1} | D | 8-4-D |

8 is a total bit width of the HiFloat8 data, and a bit width of the mantissa field may be changed. The sign field occupies one bit. 0 represents a positive number, and 1 represents a negative number; or 1 represents a negative number, and 0 represents a positive number. The prefix code field occupies two or three bits, the prefix code field may represent five different pieces of information, and a value of D may be 0, 1, 2, 3, or 4. A bit width of the exponent field changes with the value of D, and the mantissa field occupies a remaining bit width. For the prefix code field, integer coding may be used, and in this case, D is a fixed value. For the prefix code field, prefix code coding may alternatively be used, and in this case, D is a finite value set. In the prefix code coding, two bits are used to code values 2, 3, and 4, and three bits are used to code values 0 and 1. A coding scheme of the prefix code field is shown in Table 2. Table 2 shows a coding scheme of the prefix code field.

TABLE 2
Coding scheme of a prefix code field

| Value | Code | Bit width |
|---|---|---|
| 4 | 11 | 2 |
| 3 | 10 | |
| 2 | 01 | |
| 1 | 001 | 3 |
| 0 | 000 | |

It may be learned from Table 2 that, when the bit width is 2 bits, the value “4” may be coded by using “11”, the value “3” may be coded by using “10”, and the value “2” may be coded by using “01”. When the bit width is three bits, the value “1” may be coded by using “001”, and the value “0” may be coded by using “000”. The coding scheme shown in Table 2 is merely an example for description, and constitutes no limitation on this embodiment of this disclosure.

Further, a formula of conversion between HiFloat8 data and a decimal value (X) provided in this embodiment of this disclosure is:

X=(−1)^{S}*2^{E}^{+E}^{_{c}}*(1+M).

E_{c} is an exponential symmetric center, and is also a bias in FP32 data.

When D is 0, it represents that a value of the exponent field is 0. When D is not 0, signed magnitude value coding is used for the exponent field. To be specific, a sign bit is tailed with a true form (TF), and a code of the exponent field is Eᵢ={Se, 1′b1, TF[2:end]}, where Se is a sign bit of the exponent field. If the MSB 1′b1 of TF is hidden and not stored, the coded value of the exponent field is Es={Se, TF[2:end]}. A coded value of the exponent field in decimal is Ev=Eᵢ+E_{c}.

HiFloat(N, 5, E_{c}) may be configured to be HiFloat(8, 5, 0), HiF8 for short, or there may be other configurations. Distribution of HiFloat8 coded values is shown in Table 3.

TABLE 3
HiFloat8 coded value distribution table

| D | 0 | 1 | 2 | 3 | 4 |
|---|---|---|---|---|---|
| Eₛ | None | Se | Se, TF[2] | Se, TF[2:3] | Se, TF[2:4] |
| Eᵢ | 0 | Se, 1 | Se, 1, TF[2] | Se, 1, TF[2:3] | Se, 1, TF[2:4] |
| Eᵥ | 0 | ±1 | ±[2, 3] | ±[4, 7] | ±[8, 15] |
| M bit width | 4 | 3 | 3 | 2 | 1 |

With reference to Table 1 and Table 2, as shown in Table 3, when D=0, the bit width of the mantissa field is 8−4−0−4. When D=1, the bit width of the mantissa field=8−4−1=3. When D=2, the bit width of the mantissa field=8−3−2−3. When D=3, the bit width of the mantissa field=8−3−3=2. When D=4, the bit width of the mantissa field=8−3−4=1. It may be understood that when the bit width of the exponent field is smaller (for example, a value range is smaller), the bit width occupied by the mantissa field is larger, and value precision is higher. When the bit width of the exponent field is larger (for example, the value range is larger), the bit width occupied by the mantissa field is smaller, and the value precision is lower.

In addition, FIG. 2 is a diagram of distribution of exponent field-mantissa field bit width according to an embodiment of this disclosure. It may be learned from FIG. 2 that a smaller absolute value of the exponent field indicates a larger bit width of the mantissa field. Therefore, the second FP data may also be referred to as taper-shaped low-precision FP data. In addition, the taper-shaped low-precision FP data may also consider both a dynamic range of the data and data precision, so that a conversion error during conversion from high-precision data to a low-precision data format can be reduced, and training precision can be improved.

In some possible implementations, in addition to the foregoing normalized representation, the value X represented by the FP number may be selected to represent various special values by user-defined setting.

For example, when S=0, D=4, Eₛ=4′b1111=−15, and M=1′b0, X=0 (zero); when S=1, D=4, Eₛ=4′b1111=−15, and M=1′b0, X may represent a non-numeric value (NaN); and when D=4, Eₛ=4′b0111=15, and M=1′b1, X=positive or negative infinity (±infinity).

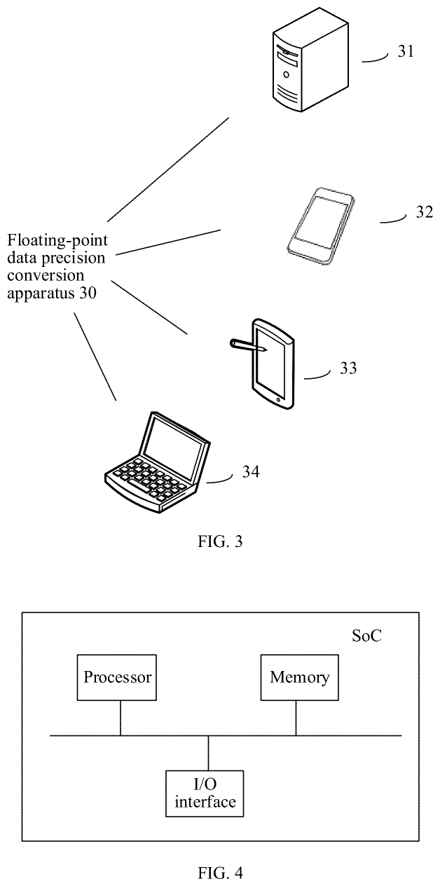

In the foregoing scenario, the FP data precision conversion method and apparatus in this disclosure may be used in different systems or devices, for example, used in an FP data precision conversion apparatus 30 shown in FIG. 3. FIG. 3 is a diagram of a system or device in which an FP data precision conversion apparatus is used according to an embodiment of this disclosure. The FP data precision conversion apparatus may be a terminal, for example, a server 31, a mobile phone terminal 32, a tablet computer 33, a notebook computer 34, an augmented reality (AR) device (not shown in FIG. 3), a virtual reality (VR) device (not shown in FIG. 3), or an in-vehicle terminal (not shown in FIG. 3). The FP data precision conversion method provided in this disclosure may be applied to a scenario related to mixed precision computation, such as a CPU, high-performance computing (HPC), and AI, in the FP data precision conversion apparatus 30, for example, a scalar computation unit, a vector computation unit, a matrix computation unit, and a tensor computation unit.

In some embodiments, the FP data precision conversion apparatus provided in this disclosure may be a chip. For example, the chip is an SoC. FIG. 4 is a diagram of a structure of a SoC according to an embodiment of this disclosure. The SoC includes a processor. The processor may be a single-core processor or a multi-core processor, a memory, an input/output (I/O) interface, or the like. After loading data and a disclosure program in the memory, the processor may process the data, for example, perform computation processing in this disclosure. For example, when the data is FP32 data, a coded value of a second mantissa field in second FP data may be determined by reading a coded value of a first exponent field in the FP32 data.

The method is applied to the foregoing system or device. The following describes a procedure of an FP data precision conversion method provided in embodiments of this disclosure.

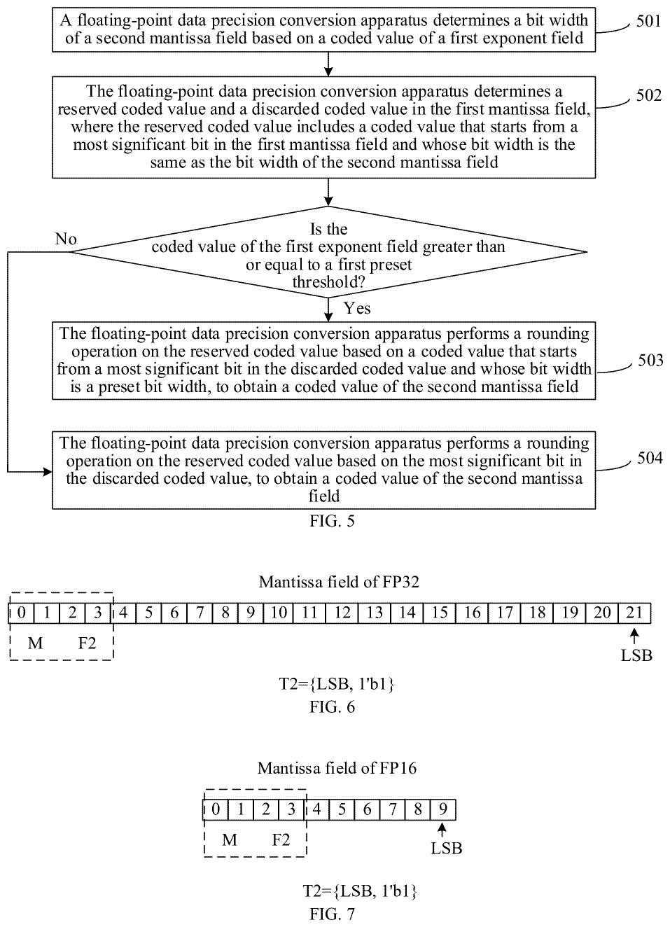

An embodiment of this disclosure provides an FP data precision conversion method. FIG. 5 is a flowchart of an FP data precision conversion method according to an embodiment of this disclosure. The method is applied to converting first FP data into second FP data. The first FP data may include a first exponent field and a first mantissa field, and the second FP data may include a second mantissa field. The method includes the following procedure.

Step 501: An FP data precision conversion apparatus determines a bit width of the second mantissa field based on a coded value of the first exponent field.

For example, precision of the first FP data is higher than precision of the second FP data, where the first FP data may be FP32 data or FP16 data, and the second FP data may be HiFloat8 data.

During conversion, a bit width of a mantissa field of the HiFloat8 data is variable. In other words, the bit width of the second mantissa field is variable, and the bit width ranges from 1 to 4. It may be understood that a larger bit width of the mantissa field indicates higher precision of the HiFloat8 data.

For example, the first FP data is FP32 data. If the coded value of the first exponent field is 8′b01111100, representing 124 in decimal, and a bias in the FP32 data (where for the FP32 data, the bias is 127) is removed, the first exponent field of the FP32 data is the −3^{rd} power of 2. With reference to Table 2 and Table 3, it can be learned that the bit width of the second mantissa field is 2.

Step 502: The FP data precision conversion apparatus determines a reserved coded value and a discarded coded value in the first mantissa field, where the reserved coded value includes a coded value that starts from an MSB in the first mantissa field and whose bit width is the same as the bit width of the second mantissa field.

For example, the precision of the first FP data is higher than the precision of the second FP data, and a bit width of a first mantissa field of the first FP data is greater than the bit width of the second mantissa field of the second FP data. Therefore, if the first FP data is converted into the second FP data, because the bit width of the second mantissa field of the second FP data is limited, rounding needs to be performed on a coded value in the first mantissa field. The coded value that starts from the MSB and whose bit width is the same as the bit width of the second mantissa field in the first mantissa field is determined as the reserved coded value, and the remaining coded value other than the reserved coded value in the first mantissa field is determined as the discarded coded value.

An example in which the first FP data is FP32 is still used. If the coded value of the first mantissa field is 23′b01000000000000000000000, because the bit width of the second mantissa field is 2, the reserved coded value is 2′b01.

Step 503: If the coded value of the first exponent field is greater than or equal to a first preset threshold, the FP data precision conversion apparatus performs a rounding operation on the reserved coded value based on a coded value that starts from an MSB and whose bit width is a preset bit width in the discarded coded value, to obtain a coded value of the second mantissa field.

For example, a manner of performing the rounding operation on the reserved coded value based on the coded value that starts from the MSB and whose bit width is the preset bit width in the discarded coded value may be understood as an SR manner. The preset bit width may be an integer from 1 to 14. A random number is introduced into the SR rounding manner, and a rounding operation is performed on the reserved coded value based on a comparison result between the random number and the coded value that starts from the MSB and whose bit width is the preset bit width in the discarded coded value. It may be understood that, the random number in the SR rounding manner is related to the discarded coded value, no additional random number generator may be required, and there is no performance bottleneck of random number generation. Therefore, the SR rounding manner not only improves efficiency of converting high-precision data into low-precision data, but also reduces hardware overheads.

Step 504: If the coded value of the first exponent field is less than the first preset threshold, the FP data precision conversion apparatus performs a rounding operation on the reserved coded value based on the MSB of the discarded coded value, to obtain the coded value of the second mantissa field.

For example, a manner of performing the rounding operation on the reserved coded value based on the MSB of the discarded coded value may be understood as a TA rounding manner. In the TA rounding manner, the MSB of the discarded coded value may be compared with the preset threshold, and the rounding operation is performed on the reserved coded value based on the comparison result. In comparison with other rounding manners, in the TA rounding manner, a hardware implementation area is smaller, power consumption overheads are less, and a data resolution is higher.

Therefore, the SR rounding manner and the TA rounding manner may be understood as an HR manner. In the HR manner, the SR rounding manner is used for data on two sides that is in a small proportion of Gaussian-like distribution, that is, main data that affects an average value. For intermediate data in a large proportion, the TA rounding manner is used. The HR manner may be applied to both the FP32 data and the FP16 data. In comparison with the TA rounding manner or the SR rounding manner, in the HR manner, better mean invariance is provided, and hardware overheads are less.

Optionally, the rounding operation includes a carrying operation and a discarding operation, and step 503 may include: When the coded value that starts from the MSB and whose bit width is the preset bit width in the discarded coded value is greater than or equal to a second preset threshold, the FP data precision conversion apparatus performs a carrying operation on an LSB of the reserved coded value, and performs a discarding operation on the discarded coded value, where a coded value obtained through the carrying operation performed on the reserved coded value is the coded value of the second mantissa field. When the coded value that starts from the MSB and whose bit width is the preset bit width in the discarded coded value is less than the second preset threshold, a discarding operation is performed on the discarded coded value, where the reserved coded value is the coded value of the second mantissa field. The second preset threshold is a coded value that starts from an LSB and whose bit width is the preset bit width in the discarded coded value.

For example, for the SR rounding manner, the preset bit width may be an integer from 1 to 14. An example in which the preset bit width is 14 bits is used. The second preset threshold may be a coded value that starts from an LSB and whose bit width is 14 in the discarded coded value. In this case, a part of the discarded coded value that is used to be compared with the second preset threshold is a coded value that starts from the MSB and whose bit width is 14 in the discarded coded value. An example in which the coded value of the first mantissa field is 23′b01000000000000000000000 is still used. In this case, the bit width of the second mantissa field is 2. In this case, the reserved coded value in the first mantissa field is 2′b01, the discarded coded value is 21′b000000000000000000000, the part of the discarded coded value is 14′b00000000000000, and the second preset threshold is 14′b00000000000000. Because the part of the discarded coded value is equal to the second preset threshold, a discarding operation is performed on the discarded coded value, and the coded value obtained through carrying of the reserved coded value is the coded value of the second mantissa field, that is, the coded value of the second mantissa field is 2′b01.

In an example, FIG. 6 is a diagram of a mantissa field of FP32 data converted into HiFloat8 data in an SR rounding manner according to an embodiment of this disclosure. An LSB in the mantissa field of the FP32 data is selected to form a 2-bit second preset threshold T2={LSB, 1′b1}. First four bits in the discarded coded value may be selected to form F2, that is, F2 is the reserved coded value, and M is the reserved coded value after the rounding operation.

In another example, FIG. 7 is a diagram of a mantissa field of FP16 data converted into HiFloat8 data in an SR rounding manner according to an embodiment of this disclosure. An LSB in the mantissa field of the FP16 data is selected to form a 2-bit second preset threshold T2={LSB, 1′b1}. First four bits in the discarded coded value may be selected to form F2.

Applicable to the mantissa field in FIG. 6 and FIG. 7, SR rounding is defined as: if F2≥T2, M+1, else M. In other words, if F2 is greater than or equal to T2, a carrying operation is performed on the reserved coded value. If F2 is less than T2, a discarding operation is performed on the discarded coded value.

In another implementation, any bit width in the first mantissa field of the first FP data is used as the second preset threshold in a manner of {aₙ, 1} or {negate(aₙ), 1}, where a negate operation represents a meaning of negation of 0 and 1, negate(0)=1, and negate(1)=0. The part of the discarded coded value in the first mantissa field is compared with the second preset threshold, to obtain an SR rounding result. In an example, the preset bit width is one bit. If the MSB of the discarded coded value is 0, {1′b0, 1′b1}=0.25, and a discarding operation is performed on the discarded coded value. If the MSB of the discarded coded value is 1, {1′b1, 1′b1}=0.75, and a carrying operation is performed on the LSB of the reserved coded value.

An error of single data in the SR rounding manner is 0.75 unit in the last place (ulp), and the error is less than 1 ulp of standard stochastic rounding. In addition, if data is evenly distributed, mean invariance of the SR rounding manner is better than mean invariance of the standard stochastic rounding.

Optionally, the rounding operation includes a carrying operation and a discarding operation, and step 504 may include: When the MSB of the discarded coded value is greater than or equal to a third preset threshold, the FP data precision conversion apparatus performs a carrying operation on the LSB of the reserved coded value, and performs a discarding operation on the discarded coded value, where a coded value obtained through carrying of the reserved coded value is the coded value of the second mantissa field. When the MSB of the discarded coded value is less than the third preset threshold, a discarding operation is performed on the discarded coded value, and the reserved coded value is the coded value of the second mantissa field.

For example, for the TA rounding manner, the third preset threshold may be 1. In an example, when the MSB of the discarded coded value is 1, a carrying operation is performed on the LSB of the reserved coded value, and a discarding operation is performed on the discarded coded value. In another example, when the MSB of the discarded coded value is 0, a discarding operation is performed on the discarded coded value.

For the TA rounding manner, the third preset threshold may alternatively be 0. When the MSB of the discarded coded value is greater than 0, a carrying operation is performed on the LSB of the reserved coded value, and a discarding operation is performed on the discarded coded value. The coded value obtained by performing the carrying operation on the reserved coded value is the coded value of the second mantissa field. When the MSB of the discarded coded value is less than or equal to 0, a discarding operation is performed on the discarded coded value, and the reserved coded value is a first coded value of the second mantissa field.

Optionally, the first preset threshold is determined by traversing a plurality of pieces of first FP data.

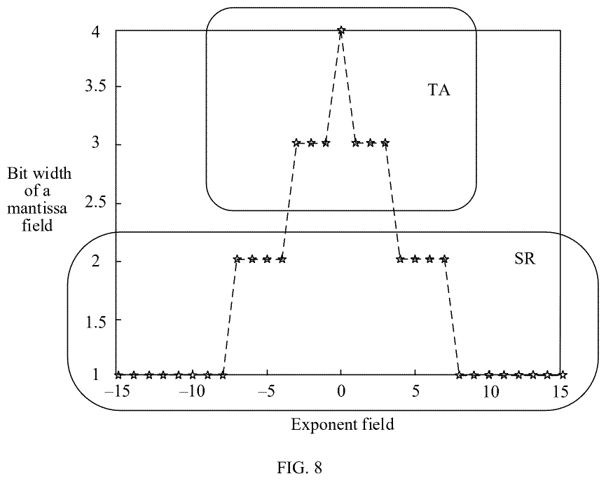

For example, the plurality of pieces of first FP data are traversed, that is, coded values of different first exponent fields are traversed, so that it can be determined that when the first preset threshold is 4, a minimum conversion error may be obtained. FIG. 8 is a diagram of distribution of an HR manner according to an embodiment of this disclosure. An exponent value of HiFloat8 is E=[−15, 15], where abs(E)=[0, 15]. If E≥4, the TA rounding manner is used. If E<4, the SR rounding manner is used.

Optionally, the first FP data further includes a sign field, the second FP data further includes the sign field, a prefix code field, and a second exponent field. The prefix code field indicates a bit width of the second exponent field. The method further includes: determining a bit width of the prefix code field, a coded value of the prefix code field, a bit width of the second exponent field, and a coded value of the second exponent field based on the coded value of the first exponent field. For example, in data format conversion, positive and negative values of data remain unchanged. To be specific, bit widths and coded values of sign fields of the first FP data and the second FP data are the same.

For the prefix code field and the second exponent field, an exponent value N of the first exponent field may be determined based on the coded value of the first exponent field. Refer to Table 1. The value of D may be determined based on the exponent value of the first exponent field. In an example, the first FP data is FP32 data. It is assumed that the coded value of the first exponent field is 8′b01111100, representing 124 in decimal. After a bias 127 for the FP32 data is removed, −3 in decimal is obtained. −3 is the exponent value N of the first exponent field, and by using a formula D=INT[log2|N|], it may be obtained that D is 2. By viewing Table 2, it may be determined that a bit width of a prefix code field corresponding to 2 is 2, a first coded value of the prefix code field is 01, and a bit width of the second exponent field is 2. Still viewing Table 3, when D is 2, and the exponent value of the first exponent field is −3, that is, the exponent sign bit Se is 1, because the bit width of the second exponent field is 2, a determined coded value of the second exponent field is 2′b11.

It may be understood that, if a carrying operation is performed on the reserved coded value, the reserved coded value may overflow. An execution device needs to first determine whether the reserved coded value obtained through the carrying operation overflows, and if the reserved coded value obtained through the carrying operation overflows, 1 is added to the LSB of the coded value of the first exponent field, to obtain a new coded value of the first exponent field. The execution device then determines a new bit width of the second exponent field and a new bit width of the prefix code field based on the new coded value of the first exponent field. If the new bit width of the prefix code field is different from an original bit width of the prefix code field, a new coded value of the prefix code field, a new coded value of the second exponent field, a new bit width of the second mantissa field, and a new coded value of the second mantissa field are determined based on the new coded value of the first exponent field. If the new bit width of the prefix code field is the same as the original bit width of the prefix code field, whether the new bit width of the second exponent field is the same as an original bit width of the second exponent field is determined. If the new bit width of the second exponent field is less than the original bit width of the second exponent field, 1 is added to the bit width of the reserved coded value, to obtain the new bit width of the second mantissa field and the new coded value of the second mantissa field. If the new bit width of the second exponent field is greater than the original bit width of the second exponent field, a discarding operation is performed on the LSB of the reserved coded value, to obtain the new bit width of the second mantissa field and the new coded value of the second mantissa field.

The FP data precision conversion method provided in embodiments of this disclosure may be applied to an NN training procedure. The NN training procedure includes model weight parameter initialization, forward computation, backward computation, a weight update procedure, and a multi-machine multi-card data communication procedure.

In a model weight parameter initialization procedure, the weight uses the high-precision FP data format. Different initialization solutions are used for different disclosure scenarios. For a training process and a pre-training process that start from zero, high-precision FP data is used for random initialization. A randomization manner is consistent with an FP16 mixed precision manner or an FP32 precision manner. For a retraining process based on FP32 or FP16 mixed precision weight, weight data obtained in an FP32 or FP16 mixed precision training process is directly loaded. An initialization manner of other parameters in a model, such as a normalization layer parameter and an optimizer parameter, is consistent with an initialization manner of a weight during training and retraining.

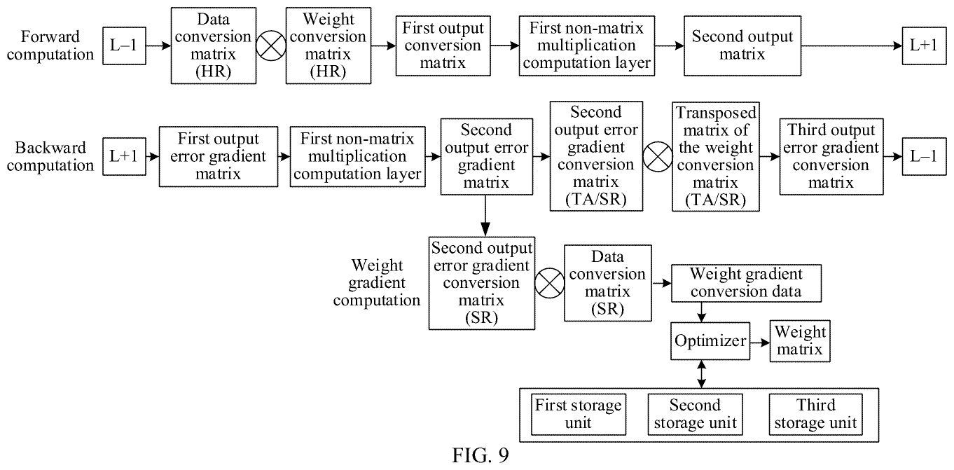

After a weight parameter is initialized, FIG. 9 is a flowchart of NN training according to an embodiment of this disclosure. L−1 represents a training process corresponding to a previous matrix multiplication computation layer of a first matrix multiplication computation layer, L+1 represents a training process corresponding to a next matrix multiplication computation layer of the first matrix computation layer, and training processes of L−1 and L+1 are the same as training processes of a data matrix and a weight matrix corresponding to the first matrix multiplication computation layer.

In a forward computation procedure, for GEMM operations at the first and intermediate layers of the network, the FP32 or the FP16 data needs to be converted into a taper-shaped low-precision FP data format, and input to a GEMM computation unit, and the FP32 or the FP16 data is output. For an activation layer and a normalization layer, the FP32 or the FP16 data is used for computation. For a tail layer of the NN, an FP32 data type or an FP16 data type is uniformly maintained. A specific procedure is: Based on a data conversion matrix and a weight conversion matrix of the first FP data format, forward computation is performed on a matrix multiplication computation layer, to obtain a first output conversion matrix of the second FP data format. A first non-matrix multiplication computation layer is obtained through forward computation performed on the first output conversion matrix, and a second output matrix in the first FP data format is obtained. The second output matrix is used as an input matrix of a next computation layer of the first non-matrix multiplication computation layer when forward computation is performed.

In a backward computation procedure, a backward procedure of the taper-shaped low-precision FP mixed precision is consistent with a backward procedure of FP16 training. An automatic scaling operation is performed. That is, a loss is multiplied by a proper scaling value, and then backward differentiation is performed. In a differentiation process of a feature map and a weight, an input of GEMM is taper-shaped low-precision FP data. A specific procedure is: A first output error gradient matrix in a second FP data format is obtained, where the first output error gradient matrix is used to update a parameter corresponding to the first non-matrix multiplication computation layer. The first non-matrix multiplication computation layer is backward propagated based on the first output error gradient matrix, to obtain a second output error gradient matrix in the first FP data format. The second output error gradient matrix is converted into a second output error gradient conversion matrix in the second FP data format, and the first matrix multiplication computation layer is backward propagated based on a second output error gradient conversion matrix and a transposed matrix of a weight conversion matrix, to obtain a third output error gradient conversion matrix in the first FP data format. The third output error gradient conversion matrix is used to update a parameter corresponding to a previous computation layer of the first matrix multiplication computation layer during forward computation of the NN.

A weight gradient computation procedure may be: inputting the second output error gradient conversion matrix and the data conversion matrix into the first matrix multiplication computation layer, to obtain weight gradient conversion data in a third data format, and updating the weight matrix based on weight gradient conversion data.

In a possible embodiment, as shown in FIG. 9, the weight matrix and other parameters may be converted into data in a high-precision data format, and the data is backed up and stored in a local storage device. For example, the weight matrix in the high-precision data format may be stored in a first storage unit w-master, a state parameter of an optimizer may be stored in a second storage unit momentum, and other parameters may be stored in a third storage unit other states.

In addition, large-scale model training is usually performed in a multi-machine manner, and involves data parallelism, model parallelism, pipeline parallelism, and a combination of the three parallel manners. A multi-machine multi-card training manner may require inter-card data communication, and the communication via the taper-shaped low-precision FP data can effectively resolve a transmission bandwidth problem.

The first FP data may be converted into the second FP data in different rounding manners in the forward computation and backward computation. This is not limited in embodiments of this disclosure.

Example 1: As shown in FIG. 9, an HR manner may be used for the forward computation, and a TA/an SR manner may be used for the backward computation.

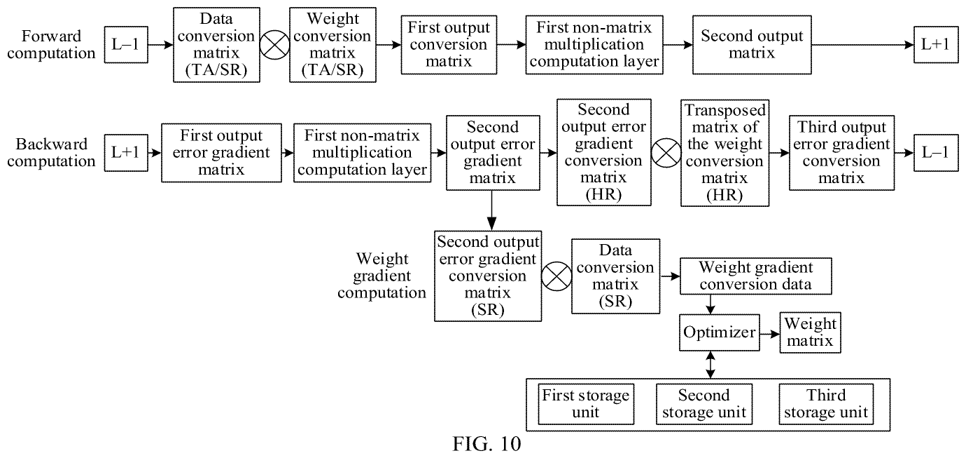

Example 2: FIG. 10 is another flowchart of NN training according to an embodiment of this disclosure. The TA/SR manner may be used for the forward computation, and the HR manner may be used for the backward computation.

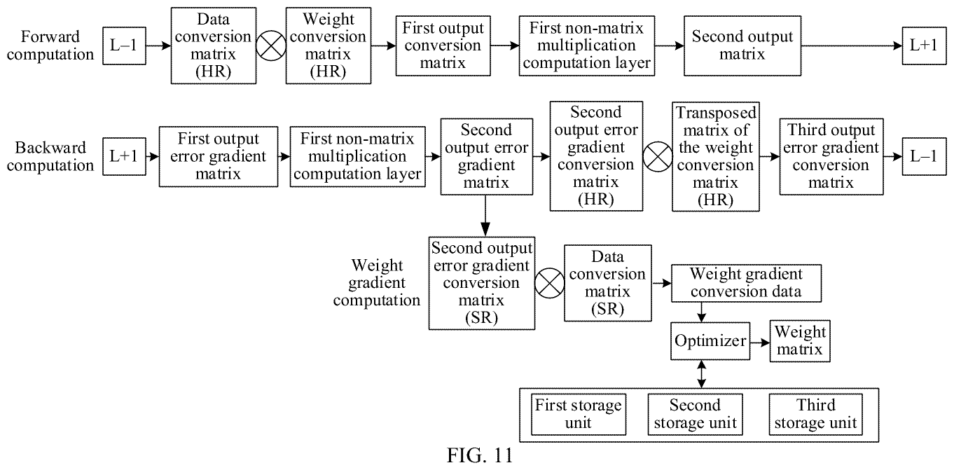

Example 3: FIG. 11 is another flowchart of NN training according to an embodiment of this disclosure. The HR manner may be used for the forward computation, and the HR manner may also be used for the backward computation.

Therefore, according to the FP data precision conversion method provided in embodiments of this disclosure, in an AI network model like a convolutional NN or a transformer model, training precision consistent with mixed precision of FP32 or FP16 can be implemented. In a bilateral mode (where the HR manner is used for both the forward computation and the backward computation), average accuracy is higher than accuracy in a unilateral mode (where the HR manner is used for the forward computation or the backward computation).

It may be understood that, to implement the foregoing functions, an electronic device includes a corresponding hardware and/or software module for performing each function. With reference to algorithm steps of examples described in embodiments disclosed in this specification, this disclosure can be implemented in a form of hardware or a combination of hardware and computer software. Whether a function is performed by hardware or hardware driven by computer software depends on particular disclosures and design constraints of the technical solutions. A person skilled in the art may use different methods to implement the described functions for each particular disclosure with reference to embodiments, but it should not be considered that the implementation goes beyond the scope of this disclosure.

In embodiments, the electronic device may be divided into functional modules based on the foregoing method examples, for example, each functional module may be obtained through division based on each corresponding function, or two or more functions may be integrated into one processing module. The integrated module may be implemented in a form of hardware. It should be noted that module division in embodiments is an example and is merely logical function division. In some implementations, there may be another division manner.

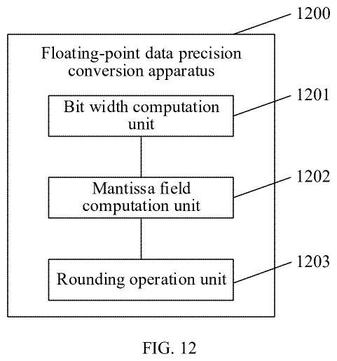

When each functional module is obtained through division based on each corresponding function, FIG. 12 is a possible diagram of composition of an FP data precision conversion apparatus 1200 in the foregoing embodiments. As shown in FIG. 12, the FP data precision conversion apparatus 1200 may include: a bit width computation unit 1201, a mantissa field computation unit 1202, and a rounding operation unit 1203.

The bit width computation unit 1201 may be configured to support the FP data precision conversion apparatus 1200 in performing step 501 and the like, and/or used in another process of the technology described in this specification.

The mantissa field computation unit 1202 may be configured to support the FP data precision conversion apparatus 1200 in performing step 502 and the like, and/or used in another process of the technology described in this specification.

The rounding operation unit 1203 may be configured to support the FP data precision conversion apparatus 1200 in performing step 503, step 504, and the like, and/or used in another process of the technology described in this specification.

It should be noted that all related content of the steps in the foregoing method embodiments may be cited in function descriptions of corresponding functional modules. Details are not described herein again.

The FP data precision conversion apparatus 1200 provided in this embodiment is configured to perform the foregoing FP data precision conversion method, and therefore can achieve the same effect as the foregoing implementation method.

When an integrated unit is used, the FP data precision conversion apparatus 1200 may include a processing module, a storage module, and a communication module. The processing module may be configured to control and manage an action of the FP data precision conversion apparatus 1200, for example, may be configured to support the FP data precision conversion apparatus 1200 in performing the steps performed by the bit width computation unit 1201, the mantissa field computation unit 1202, and the rounding operation unit 1203. The storage module may be configured to support the FP data precision conversion apparatus 1200 in storing program code, data, and the like. The communication module may be configured to support the FP data precision conversion apparatus 1200 in communicating with another device, for example, communicating with a wireless access device.

The processing module may be a processor or a controller. The processor may implement or execute various example logical blocks, modules, and circuits described with reference to content disclosed in this disclosure. The processor may alternatively be a combination for implementing a computing function, for example, a combination including one or more microprocessors or a combination of a digital signal processor (DSP) and a microprocessor. The storage module may be a memory. The communication module may be a device, such as a radio-frequency circuit, a Bluetooth chip, or a Wi-Fi chip, that interacts with another electronic device.

An embodiment of this disclosure further provides an electronic device, including one or more processors and one or more memories. The one or more memories are coupled to the one or more processors. The one or more memories are configured to store computer program code, and the computer program code includes computer instructions. When the one or more processors execute the computer instructions, the electronic device is enabled to perform the foregoing related method steps, to implement the FP data precision conversion method in the foregoing embodiments.

An embodiment of this disclosure further provides a computer storage medium. The computer storage medium stores computer instructions. When the computer instructions are run on an electronic device, the electronic device is enabled to perform the related method steps, to implement the FP data precision conversion method in the foregoing embodiments.

An embodiment of this disclosure further provides a computer program product. When the computer program product is run on a computer, the computer is enabled to perform the foregoing related steps, to implement the FP data precision conversion method performed by the electronic device in the foregoing embodiments.

In addition, an embodiment of this disclosure further provides an apparatus. The apparatus may be a chip, a component, or a module. The apparatus may include a processor and a memory that are connected. The memory is configured to store computer-executable instructions, and when the apparatus runs, the processor may execute the computer-executable instructions stored in the memory, to enable the chip to perform the FP data precision conversion method performed by the electronic device in the foregoing method embodiments.

The electronic device, the computer storage medium, the computer program product, or the chip provided in embodiments is configured to perform the corresponding method provided above. Therefore, for beneficial effects that can be achieved by the electronic device, the computer storage medium, the computer program product, or the chip, refer to the beneficial effects in the corresponding method provided above. Details are not described herein.

Based on the descriptions of the foregoing implementations, a person skilled in the art may understand that, for a purpose of convenient and brief description, division into the foregoing functional modules is merely used as an example for illustration. In some disclosures, the foregoing functions may be allocated to different functional modules and implemented based on requirements. In other words, an inner structure of an apparatus is divided into different functional modules, to implement all or some of the functions described above.

In the several embodiments provided in this disclosure, it should be understood that the disclosed apparatus and method may be implemented in other manners. For example, the described apparatus embodiment is merely an example. For example, the module or division into the units is merely logical function division and may be other division in some implementations. For example, a plurality of units or components may be combined or integrated into another apparatus, or some features may be ignored or not performed. In addition, the displayed or discussed mutual couplings or direct couplings or communication connections may be implemented through some interfaces. The indirect couplings or communication connections between the apparatuses or units may be implemented in electronic, mechanical, or other forms.

The units described as separate parts may or may not be physically separate, and parts displayed as units may be one or more physical units, may be located in one place, or may be distributed on different places. Some or all of the units may be selected based on example requirements to achieve the objectives of the solutions of embodiments.

In addition, functional units in embodiments of this disclosure may be integrated into one processing unit, each of the units may exist alone physically, or two or more units are integrated into one unit. The integrated unit may be implemented in a form of hardware, or may be implemented in a form of a software functional unit.

When the integrated unit is implemented in the form of a software functional unit and sold or used as an independent product, the integrated unit may be stored in a readable storage medium. Based on such an understanding, the technical solutions in embodiments of this disclosure essentially, or the part contributing to the related art, or all or some of the technical solutions may be implemented in the form of a software product. The software product is stored in a storage medium and includes several instructions for instructing a device (which may be a single-chip microcomputer, a chip or the like) or a processor to perform all or some of the steps of the methods described in embodiments of this disclosure. The storage medium includes various media that can store program code, such as a universal serial bus (USB) flash drive, a removable hard disk, a read-only memory (ROM), a random-access memory (RAM), a magnetic disk, or an optical disc.

The foregoing descriptions are merely specific implementations of this disclosure, but are not intended to limit the protection scope of this disclosure. Any variation or replacement readily figured out by a person skilled in the art in the technical scope disclosed in this disclosure shall fall within the protection scope of this disclosure. Therefore, the protection scope of this disclosure shall be subject to the protection scope of the claims.

1. A method, comprising:
determining a first bit width of a second mantissa field of second floating-point data based on a first coded value of a first exponent field of first floating-point data, wherein the first floating-point data is more precise than the second floating-point data;
determining a reserved coded value and a discarded coded value of a first mantissa field of the first floating-point data, wherein the reserved coded value comprises a second coded value that starts from a first most significant bit of the first mantissa field, and wherein a second bit width of the second coded value is equal to the first bit width;
performing, when the first coded value is greater than or equal to a first preset threshold, first rounding operation on the reserved coded value based on a third coded value that starts from a second most significant bit of the discarded coded value to obtain a fourth coded value of the second mantissa field, wherein a third bit width of the third coded value is a preset bit width; and
performing, when the first coded value of the first exponent field is less than the first preset threshold, a second rounding operation on the reserved coded value based on the second most significant bit to obtain the fourth coded value.

2. The method of claim 1, wherein performing the first rounding operation comprises:
when the third coded value is greater than or equal to a second preset threshold, performing a carrying operation on a first least significant bit of the reserved coded value to obtain a fifth coded value, and performing a first discarding operation on the discarded coded value, wherein the fifth coded value is the fourth coded value; or
when the third coded value is less than the second preset threshold, performing a second discarding operation on the discarded coded value, wherein the reserved coded value is the fourth coded value,
wherein the second preset threshold is a sixth coded value that starts from a second least significant bit of the discarded coded value, and wherein a fourth bit width of the sixth coded value is the preset bit width.

3. The method of claim 1, wherein performing the second rounding operation comprises:
when the second most significant bit is greater than or equal to a second preset threshold, performing a carrying operation on a first least significant bit of the reserved coded value to obtain a fifth coded value, and performing a first discarding operation on the discarded coded value, wherein the fifth coded value is the fourth coded value; or
when the second most significant bit is less than the second preset threshold, performing a second discarding operation on the discarded coded value, wherein the reserved coded value is the fourth coded value.

4. The method of claim 1, wherein the first preset threshold is based on traversing a plurality of pieces of the first floating-point data.

5. The method of claim 1, wherein the first floating-point data further comprises a first sign field, wherein the second floating-point data further comprises a second sign field, a prefix code field, and a second exponent field, wherein the prefix code field indicates a fourth bit width of the second exponent field, and wherein the method further comprises determining, before determining the first bit width, a fifth bit width of the prefix code field, a fifth coded value of the prefix code field, the fourth bit width of the second exponent field, and a sixth coded value of the second exponent field based on the first coded value.

6. An apparatus, comprising:
a memory configured to store computer instructions; and
a processor coupled to the memory and configured to execute the computer instructions to cause the apparatus to:
determine a first bit width of a second mantissa field of second floating-point data based on a first coded value of a first exponent field of first floating-point data, wherein the first floating-point data is more precise than the second floating-point data;
determine a reserved coded value and a discarded coded value of a first mantissa field of the first floating-point data, wherein the reserved coded value comprises a second coded value that starts from a first most significant bit of the first mantissa field, and wherein a second bit width of the second coded value is equal to the first bit width;
perform, when the first coded value is greater than or equal to a first preset threshold, a first rounding operation on the reserved coded value based on a third coded value that starts from a second most significant bit of the discarded coded value to obtain a fourth coded value of the second mantissa field, wherein a third bit width of the third coded value is a preset bit width; and
perform, when the first coded value is less than the first preset threshold, a second rounding operation on the reserved coded value based on the second most significant bit to obtain a coded the fourth coded value.

7. The apparatus of claim 6, wherein processor is further configured to execute the computer instructions to cause the apparatus to further perform the first rounding by:
when the third coded value is greater than or equal to a second preset threshold, performing a carrying operation on a first least significant bit of the reserved coded value to obtain a fifth coded value, and performing a first discarding operation on the discarded coded value, wherein the fifth coded value is the fourth coded value; or
when the third coded value is less than the second preset threshold, performing a second discarding operation on the discarded coded value, wherein the reserved coded value is the fourth coded value,
wherein the second preset threshold is a sixth coded value that starts from a second least significant bit of the discarded coded value, and wherein a fourth bit width of the sixth coded value is the preset bit width.

8. The apparatus of claim 6, wherein the processor is further configured to execute the computer instructions to further cause the apparatus to:
when the second most significant bit is greater than or equal to second preset threshold, perform a carrying operation on a first least significant bit of the reserved coded value to obtain a fifth coded value, and perform a first discarding operation on the discarded coded value, wherein the fifth coded value is the fourth coded value; or
when the second most significant bit is less than the second preset threshold, perform a second discarding operation on the discarded coded value, wherein the reserved coded value is the fourth coded value.

9. The apparatus of claim 6, wherein the first preset threshold is based on traversing a plurality of pieces of the first floating-point data.

10. The apparatus of claim 6, wherein the first floating-point data further comprises a first sign field, wherein the second floating-point data further comprises a second sign field, a prefix code field, and a second exponent field, wherein the prefix code field indicates a fourth bit width of the second exponent field, and wherein the processor is further configured to execute the computer instructions to further cause the apparatus to determine, before determining the first bit width, a fifth bit width of the prefix code field, a fifth coded value of the prefix code field, the fourth bit width of the second exponent field, and a sixth coded value of the second exponent field based on the first coded value.

11. A computer-readable storage medium comprising computer instructions, wherein when an electronic device executes the computer instructions, the computer instructions cause the electronic device to:
determine a first bit width of a second mantissa field of second floating-point data based on a first coded value of a first exponent field of first floating-point data, wherein the first floating-point data is more precise than the second floating-point data;
determine a reserved coded value and a discarded coded value of a first mantissa field of the first floating-point data, wherein the reserved coded value comprises a second coded value that starts from a first most significant bit of the first mantissa field, and wherein a second bit width of the second coded value is equal to the first bit width;
perform, when the first coded value is greater than or equal to a first preset threshold, a first rounding operation on the reserved coded value based on a third coded value that starts from a second most significant bit of the discarded coded value to obtain a fourth coded value of the second mantissa field, wherein a third bit width of the third coded value is a preset bit width; and
perform, when the first coded value of the first exponent field is less than the first preset threshold, a second rounding operation on the reserved coded value based on the second most significant bit to obtain the fourth coded value.

12. The computer-readable storage medium of claim 11, wherein, when the electronic device is further configured to execute the computer instructions, the computer instructions cause the electronic device to further perform the first rounding by:
when the third coded value is greater than or equal to a second preset threshold, performing a carrying operation on a first least significant bit of the reserved coded value to obtain a fifth coded value, and performing a first discarding operation on the discarded coded value, wherein the fifth coded value is the fourth coded value; or
when the third coded value is less than the second preset threshold, performing a second discarding operation on the discarded coded value, wherein the reserved coded value is the fourth coded value,
wherein the second preset threshold is a sixth coded value that starts from a second least significant bit of the discarded coded value, and wherein a fourth bit width of the sixth coded value is the preset bit width.

13. The computer-readable storage medium of claim 11, wherein, when the electronic device is further configured to execute the computer instructions, the computer instructions further cause the electronic device to:
when the second most significant bit is greater than or equal to a second preset threshold, perform a carrying operation on a first least significant bit of the reserved coded value to obtain a fifth coded value, and perform a first discarding operation on the discarded coded value, wherein the fifth coded value is the fourth coded value; or
when the second most significant bit is less than the second preset threshold, perform a second discarding operation on the discarded coded value, wherein the reserved coded value is the fourth coded value.

14. The computer-readable storage medium of claim 11, wherein the first preset threshold is based on traversing a plurality of pieces of the first floating-point data.

15. The computer-readable storage medium of claim 11, wherein the first floating-point data further comprises a first sign field, wherein the second floating-point data further comprises a second sign field, a prefix code field, and a second exponent field, wherein the prefix code field indicates a fourth bit width of the second exponent field, and, wherein, when the electronic device is further configured to execute the computer instructions, the computer instructions further cause the electronic device to determine, before determining the first bit width, a fifth bit width of the prefix code field, a fifth coded value of the prefix code field, the fourth bit width of the second exponent field, and a sixth coded value of the second exponent field based on the first coded value.

16. The method of claim 1, further comprising training a neural network using the first floating-point data or the second floating-point data.

17. The method of claim 16, wherein training the neural network comprises:
performing general matrix multiplication including convolution, transposed convolution, matrix multiplication, and batch matrix multiplication using the first floating-point data or the second floating-point data; and
performing non-general matrix multiplication including a sigmoid function, a tanh function, a rectified linear unit function, a batch normalization function, a layer normalization function, an instance normalization function, and an optimizer gradient update computation using the first floating-point data or the second floating-point data.

18. The apparatus of claim 6, wherein the processor is further configured to execute the computer instructions to further cause the apparatus to train a neural network using the first floating-point data or the second floating-point data.

19. The apparatus of claim 18, wherein the processor is further configured to execute the computer instructions to cause the apparatus to further train the neural network by:
performing general matrix multiplication including convolution, transposed convolution, matrix multiplication, and batch matrix multiplication using the first floating-point data or the second floating-point data; and
performing non-general matrix multiplication including a sigmoid function, a tanh function, a rectified linear unit function, a batch normalization function, a layer normalization function, an instance normalization function, and an optimizer gradient update computation using the first floating-point data or the second floating-point data.

20. The computer-readable storage medium of claim 11, wherein, when the electronic device is further configured to execute the computer instructions, the computer instructions further cause the electronic device to train a neural network using the first floating-point data or the second floating-point data.
